(19) United States
(12) Patent Application Publication
(10) Pub. No.: US 2002/0196654 A1
(43) Pub. Date: Dec. 26, 2002

(54) Semiconductor memory device

(75) Inventors: Shun Mitarai, Kanagawa (JP); Tsutomu Nagahama, Kanagawa (JP); Kenji Katori, Kanagawa (JP)

Correspondence Address: SONNENSCHEIN NATH & ROSENTHAL, P.O. BOX 061080, WACKER DRIVE STATION, CHICAGO, IL, 60606-1080, US

(73) Assignee: Sony Corporation

(21) Appl. No.: 10/165,393

(22) Filed: Jun. 7, 2002

(30) Foreign Application Priority Data
Jun. 8, 2001 (JP) P2001-174089

(51) Int. Cl. G11C 11/22

(52) U.S. Cl. 365/145

(57) ABSTRACT

A semiconductor memory device comprising; (A) a transistor, (B) a capacitor member formed above said transistor through an insulating interlayer, said capacitor member comprising a lower electrode, a capacitor layer formed of a high-dielectric-constant material or a ferroelectric material and an upper electrode, (C) a contact plug formed in said insulating interlayer, for electrically connecting the lower electrode formed on the insulating interlayer with the transistor, and (D) a diffusion barrier layer formed between the lower electrode and the contact plug, said semiconductor memory device further comprising (E) an adhesion layer formed at least between the lower electrode and the diffusion barrier layer, and said adhesion layer consisting of an alloy that contains a noble metal element as a main component, and contains, as a component, a metal element that differs from any one of the noble metal element, an alkali element and an alkaline earth metal element and that contains no oxygen atom.

### BACKGROUND OF THE INVENTION AND RELATED ART STATEMENT

The present invention relates to a semiconductor memory device having a capacitor member provided with a capacitor layer formed of a high-dielectric-constant material or a ferroelectric material.

In recent years, the integration density of a semiconductor memory device is being increased, and it is accordingly strongly demanded to decrease the area of a capacitor member. In a semiconductor memory device typified by a dynamic random access memory (DRAM), conventionally, a capacitor layer constituting the capacitor member is formed of SiO₂ or SiN. Since, however, these materials have a low relative dielectric constant, it is getting more difficult to secure the capacitance required for storing data with a decrease in the area of the capacitor member.

For overcoming the above problem, one solution under study is to use a high-dielectric-constant material such as BaTiO₃ (barium titanate) or (Ba, Sr)TiO₂ (barium-strontium titanate) for the capacitor layer.

In recent years, studies are actively made with regard to a large-capacity ferroelectric nonvolatile semiconductor memory device (so-called FERAM). The ferroelectric nonvolatile semiconductor memory device (to be sometimes referred to as “nonvolatile memory” hereinafter) permits fast access and has nonvolatility, and it is small in size and serves to reduce power consumption. Further, it has high resistance to an impact, and there is much expectation that it can be applied to main memories of various electronic machines having file storage means or a resuming function such as a portable computer, a cellular phone and a game machine, or that it can be applied to a recording medium for recording voices and images.

The above nonvolatile memory is a fast rewritable nonvolatile memory employing a method in which fast polarization inversion of a ferroelectric thin film and residual polarization thereof are used to detect a change in an accumulated charge amount of a capacitor member provided with a capacitor layer formed from a ferroelectric material. In principle, the nonvolatile memory comprises the capacitor member (memory cell) and a transistor (transistor for selection). The capacitor member comprises, for example, a lower electrode, an upper electrode and the capacitor layer formed of a ferroelectric material that is sandwiched between these electrodes and has a high relative dielectric constant ∈. Examples of the ferroelectric material include SrBi₂Ta₂O₉ and Pb(Zr,Ti)O₃.

Write-in and read-out of data in the above nonvolatile memory is carried out by using a P-E hysteresis loop of the ferroelectric material shown in FIG. 11. That is, when an external electric field is applied to the capacitor layer and then removed, the capacitor layer shows a residual polarization. And, the residual polarization of the capacitor layer comes to be +Pᵣ when an external electric field in the plus direction is applied, and it comes to be −Pᵣ when an external electric field in the minus direction is applied. In this loop, a case where the residual polarization is in a +Pᵣ state (see “D” in FIG. 11) is determined to be “0”, and a case where the residual polarization is in a −Pᵣ state (see “A” in FIG. 11) is determined to be “1”.

For discriminating between a state “1” and a state “0”, an external electric field, for example, in the plus direction is applied to the capacitor layer formed of the ferroelectric material, whereby the polarization of the capacitor layer comes to be in a state “C” in FIG. 11. In this case, when data is “0”, the polarization state of the capacitor layer changes from “D” to “C”. On the other hand, when data is “1”, the polarization state of the capacitor layer changes from “A” to “C” through “B”. When data is “0”, no polarization inversion takes place in the capacitor layer. When data is “1”, a polarization inversion takes place in the capacitor layer. As a result, there is caused a difference in an accumulated charge amount. By switching on the transistor for selection in a selected nonvolatile memory, the accumulated charge is detected as a signal current. When the external electric field is turned to 0 after data is read out, the polarization state of the capacitor layer comes to be in the state of “D” in FIG. 11 in both occasions when the data is “0”and when the data is “1”. That is, when data is read out, data “1” is once destroyed. When the data is “1”, therefore, an external electric field in the minus direction is applied to rewrite data “1” by producing a state of “A” from “D” through “E”.

For increasing the density of integration of the above various semiconductor memory devices, it is required to decrease the cell area thereof and at the same time it is required to employ a so-called stacked capacitor structure in which the capacitor members are three-dimensionally arranged above the transistors. In the stacked capacitor structure, the capacitor members are formed above the transistors through an insulating interlayer. Each of the above capacitor members comprises a lower electrode, a capacitor layer and an upper electrode. The lower electrode is formed on the insulating interlayer, and the lower electrode and the transistor are electrically connected to each other through a contact plug formed in the insulating interlayer. Generally, the contact plug is formed of an electrically conductive material such as polycrystalline silicon or tungsten.

Meanwhile, when atomic interdiffusion takes place between a material forming the lower electrode and a material forming the contact plug due to heat treatment during the manufacturing of the capacitor members, the semiconductor memory device is degraded in properties, or downgraded in reliability. Generally, a diffusion barrier layer is therefore formed between the lower electrode and the contact plug. The diffusion barrier layer is formed, for example, of TiN, TaN or TiAlN.

The above high-dielectric-constant material or ferroelectric material is mainly an oxide, and for forming the capacitor layer therefrom, it is required to carry out heat treatment under a high-temperature oxygen-containing atmosphere. When such heat treatment is carried out, oxygen passes through the lower electrode to reach the contact plug in some cases. When such a phenomenon takes place, the top surface of the contact plug is oxidized, so that there is caused a problem that electric conduction can be no longer performed. Further, when a material forming the diffusion barrier layer is oxidized, it loses electric conduction.

As a material for the lower electrode, therefore, it is required to select a material that is stable under a high-temperature oxygen-containing atmosphere and has oxygen-barrier properties. It is general practice to use a noble metal material or an oxide thereof such as iridium (Ir) or iridium oxide (IrO₂).

As described above, when a high-dielectric-constant material or a ferroelectric material is applied to the stacked capacitor structure, a lower electrode having oxygen barrier properties and a diffusion barrier layer are used in combination in many cases.

However, the noble metal material or oxide thereof for constituting the lower electrode has poor reactivity, so that they are generally poor in adhesion to other material. When the heat treatment is carried out, therefore, peeling is liable to occur between the diffusion barrier layer and the lower electrode due to a stress. When the lower electrode peels off, oxygen penetrate a gap formed by the peeling, and the diffusion barrier layer and the contact plug formed thereunder are oxidized, so that there is caused a problem that the lower electrode cannot exhibit the oxygen barrier properties that the lower electrode inherently has. Particularly, SrBi₂Ta₂O₉ that has excellent durability against repeated read-out and write-in of data and is being applied to the nonvolatile memory has a crystallization temperature of 700° C. to 800° C., so that it causes a great heat load on the lower electrode during the manufacturing of the capacitor member. It is therefore difficult to apply SrBi₂Ta₂O₉ to the stacked capacitor structure.

For preventing the above peeling of the lower electrode, for example, JP-A-11-214641 discloses a technique of forming an adhesion layer of a metal oxide such as TiOₓ or IrO₂ or an alloy oxide such as Ti—Ru—Oₓ between the lower electrode and the diffusion barrier layer. However, TiOₓ cannot be applied to the stacked capacitor structure since it has not electric conductivity, and it can be applied only to a planar capacitor structure. Further, IrO₂ and Ti—Ru—Oₓ have electric conductivity but contain oxygen, so that there is a fear that oxygen atoms are diffused in a structure in which the adhesion layer is directly in contact with the diffusion barrier layer, and that a contact resistance may accordingly increase.

There is known a method in which, as a combination of materials for the lower electrode and the diffusion barrier layer, Pt and TiN are combined (for example, JP-A-10-214944) or Ir and Ti are combined (for example, JP-A-11-31791) and the lower electrode is heat-treated before the formation of the capacitor layer to form an alloy layer according to a reaction between the lower electrode and the diffusion barrier layer for improving the adhesion between the lower electrode and the diffusion barrier layer. However, the method of forming the above alloy layer has a problem that the adhesion between the lower electrode and the insulating interlayer cannot be improved when the diffusion barrier layer is locally present (for example, when the diffusion barrier layer is formed on the contact plug alone and is not formed on the insulating interlayer).

### OBJECT AND SUMMARY OF THE INVENTION

It is therefore an object of the present invention to provide a semiconductor memory device having a so-called stacked capacitor structure, which is so structured as to reliably prevent the peeling of the lower electrode.

According to the present invention, the above object is achieved by a semiconductor memory device comprising;

(A) a transistor,

(B) a capacitor member formed above said transistor through an insulating interlayer, said capacitor member comprising a lower electrode, a capacitor layer formed of a high-dielectric-constant material or a ferroelectric material and an upper electrode,

(C) a contact plug formed in said insulating interlayer, for electrically connecting the lower electrode formed on the insulating interlayer with the transistor, and

(D) a diffusion barrier layer formed between the lower electrode and the contact plug,

said semiconductor memory device further comprising;

(E) an adhesion layer formed at least between the lower electrode and the diffusion barrier layer, and

said adhesion layer consisting of an alloy that contains a noble metal element as a main component, and contains, as a component, a metal element that differs from any one of the noble metal element, an alkali element and an alkaline earth metal element and that contains no oxygen atom.

When the semiconductor memory device has the capacitor layer formed of a high-dielectric-constant material, a so-called DRAM is constituted of the semiconductor memory device of the present invention, and when the semiconductor memory device has the capacitor layer formed of a ferroelectric material, a so-called ferroelectric nonvolatile semiconductor memory device is constituted of the semiconductor memory device of the present invention.

The semiconductor memory device of the present invention may employ a constitution in which the adhesion layer is formed between the lower electrode and the diffusion barrier layer and between the lower electrode and the insulating interlayer. Alternatively, there may be employed a so-called damascene structure in which an insulating layer is formed on the insulating interlayer, the insulating layer has a recess having a bottom where at least the diffusion barrier layer is exposed and the adhesion layer and the lower electrode are formed in the recess. Further, the semiconductor memory device of the present invention, including the above constitution and structure, may have a constitution in which the diffusion barrier layer has a side wall surrounded by the insulating interlayer. The semiconductor memory device of the present invention, including the above constitution and structure, will be sometimes referred to as the semiconductor memory device of the present invention including preferred embodiments.

In the semiconductor memory device of the present invention including preferred embodiments, the noble metal element forming the adhesion layer is preferably an element of the platinum group, and further, the lower electrode preferably contains an element of the platinum group as a main component. In this case, desirably, the noble metal element forming the adhesion layer and the noble metal element forming the lower electrode are the same. The above element of the platinum group includes iridium (Ir), ruthenium (Ru), rhodium (Rh), palladium (Pd), osmium (Os) and platinum (Pt).

In the semiconductor memory device of the present invention including preferred embodiments, preferably, the lower electrode is formed of a noble metal or a noble metal compound and has oxygen barrier properties.

In the semiconductor memory device of the present invention including preferred embodiments, preferably, the lower electrode is formed of at least one noble metal selected from the group consisting of iridium (Ir), ruthenium (Ru), rhodium (Rh), palladium (Pd), osmium (Os) and platinum (Pt) or a compound thereof. In this case, preferably, the noble metal element forming the adhesion layer is at least one element of the platinum group selected from the group consisting of iridium (Ir), ruthenium (Ru), rhodium (Rh), palladium (Pd), osmium (Os) and platinum (Pt), and the metal element that differs from any one of the noble metal element, an alkali element and an alkaline earth metal element is at least one metal element selected from the group consisting of hafnium (Hf), aluminum (Al), titanium (Ti), vanadium (V), zirconium (zr), niobium (Nb), molybdenum (Mo), tantalum (Ta) and tungsten (W). The adhesion layer preferably has crystallinity, while it may be amorphous. The above crystallinity can be identified by means of an X-ray diffraction apparatus or a surface scanning electron microscope. Specifically, for example, the adhesion layer formed is subjected to X-ray diffraction analysis and evaluated for diffraction pattern strength (diffraction peak height) inherent to a material constituting the adhesion layer. An adhesion layer having a predetermined content of at least one metal element selected from the group consisting of hafnium (Hf), aluminum (Al), titanium (Ti), vanadium (V), zirconium (Zr), niobium (Nb), molybdenum (Mo), tantalum (Ta) and tungsten (W) has crystallinity. Further, the noble metal element forming the adhesion layer and the noble metal element forming the lower electrode are desirably the same.

When the adhesion layer contains hafnium (Hf), desirably, the content of hafnium (Hf) is 25 atomic % or less, preferably 3 atomic % to 25 atomic %, more preferably 5 atomic % to 20 atomic %.

When the adhesion layer contains aluminum (Al), desirably, the content of aluminum (Al) is 50 atomic % or less, preferably 3 atomic % to 50 atomic %, more preferably 5 atomic % to 30 atomic %.

When the adhesion layer contains titanium (Ti), desirably, the content of titanium (Ti) is 25 atomic % or less, preferably 3 atomic % to 25 atomic %, more preferably 8 atomic % to 15 atomic %.

When the adhesion layer contains vanadium (V), desirably, the content of vanadium (V) is 25 atomic % or less, preferably 3 atomic % to 25 atomic %, more preferably 12 atomic % to 20 atomic %.

When the adhesion layer contains zirconium (Zr), desirably, the content of zirconium (Zr) is 25 atomic % or less, preferably 3 atomic % to 25 atomic %, more preferably 8 atomic % to 15 atomic %.

When the adhesion layer contains niobium (Nb), desirably, the content of niobium (Nb) is 25 atomic % or less, preferably 3 atomic % to 25 atomic %, more preferably 10 atomic % to 20 atomic %.

When the adhesion layer contains molybdenum (Mo), desirably, the content of molybdenum (Mo) is 25 atomic % or less, preferably 3 atomic % to 25 atomic %, more preferably 10 atomic % to 20 atomic %.

When the adhesion layer contains tantalum (Ta), desirably, the content of tantalum (Ta) is 25 atomic % or less, preferably 3 atomic % to 25 atomic %, more preferably 5 atomic % to 15 atomic %.

When the adhesion layer contains tungsten (W), desirably, the content of tungsten (W) is 20 atomic % or less, preferably 3 atomic % to 20 atomic %, more preferably 5 atomic % to 15 atomic %.

In the semiconductor memory device of the present invention including preferred embodiments, the diffusion barrier layer is formed of a refractory metal or a refractory metal compound, and it desirably contains no oxygen element. Specific examples thereof include TiN, TaN, TiAlN, TiW and WN.

In the semiconductor memory device of the present invention including preferred embodiments, the thickness of the adhesion layer is preferably 50 nm or less, and more preferably, it is as thin as possible. The lower limit of the thickness of the adhesion layer depends upon a method of forming the adhesion layer, forming conditions and a forming apparatus. When the adhesion layer is formed, for example, by a sputtering method, the lower limit of the thickness of the adhesion layer is approximately 5 nm.

In the semiconductor memory device of the present invention including preferred embodiments, the high-dielectric-constant material for constituting the capacitor layer includes BaTiO₃ (barium titanate) and (Ba,Sr)TiO₃ (barium-strontium titanate).

The ferroelectric material for constituting the capacitor layer includes a bismuth layered compound, more specifically, a Bi-containing layered perovskite type ferroelectric material. The Bi-containing layered perovskite type ferroelectric material comes under so-called nonstoichiometric compounds, and a compositional deviation is allowed in sites of metal atoms and anions (O or the like) element. It is not rare that the above ferroelectric material exhibits optimum electric properties when the composition thereof deviates from a stoichiometric composition to some extent. The Bi-containing layered perovskite type ferroelectric material can expressed, for example, by the general formula of (Bi₂O₂)²⁺(Aₘ₋₁BₘO₃ₘ₊₁)²⁻ in which “A” is one metal selected from the group consisting of metals such as Bi, Pb, Ba, Sr, Ca, Na, K, Cd, etc., “B” is one element selected from the group consisting of Ti, Nb, Ta, W, Mo, Fe, Co and Cr or a combination of two or more elements having any content each, and m is an integer of 1 or more.

Alternatively, the ferroelectric material preferably contains, as a main crystal phase, a crystal phase of the formula (1),

(Sr_{Y},Bi_{1-Y})(Bi_{X},Sr_{1-X})₂(Ta_{Z},Nb_{1-Z})₂O_{d} (1)

wherein 0.9≦X≦1.0, 0.7≦Y≦1.0, 0≦Z≦1.0 and 8.7≦d≦9.3.

Otherwise, the ferroelectric material preferably contains, as a main crystal phase, a crystal phase of the formula (2),

Sr_{Y}Bi_{X}Ta₂O_{d} (2)

wherein X+Y=3, 0.7≦Y≦1.3 and 8.7≦d≦9.3.

In the above cases, more preferably, the ferroelectric material contains at least 85% of the crystal phase of the formula (1) or (2) as a main crystal phase. In the formula (1), (Bi_{X},Sr_{1-X}) means that Sr occupies a site that is stoichiometrically to be occupied by Bi in a crystal structure and that the amount ratio of Bi:Sr is X:(1−X). Further, (Sr_{Y},Bi_{1-Y}) means that Bi occupies a site that is stoichiometrically to be occupied by Sr in a crystal structure and that the amount ratio of Sr:Bi is Y:(1−Y). The ferroelectric material containing the crystal phase of the formula (1) or (2) as a main crystal phase may contain a Bi oxide, a Ta or Nb oxide or a composite oxide of Bi, Ta and Nb to some extent.

Alternatively, the ferroelectric material may contain a crystal phase of the formula (3),

(Sr,Ca,Ba)_{Y}Bi_{X}(Ta_{Z},Nb_{1-Z})₂O_{d} (3)

wherein 1.7≦X≦2.5, 0.6≦Y≦1.2, 0≦Z≦1.0 and 8.0≦d≦10.0. (Sr,Ca,Ba) means one element selected from the group consisting of Sr, Ca and Ba. Stoichiometric compositions of the ferroelectric material of the above formulae include, for example, SrBi₂Ta₂O₉, SrBi₂Nb₂O₉, BaBi₂Ta₂O₉, SrBi₂TaNbO₉ and the like. The ferroelectric material also includes Bi₄SrTi₄O₁₅, Bi₄Ti₃O₁₂, Bi₂PbTa₂O₉, etc. In these cases, the amount ratio of the metal elements of these may vary so long as a crystal structure thereof is not changed. That is, a composition of sites of metal elements and oxygen element may be deviated.

The ferroelectric material further includes PbTiO₃, lead titanate zirconate [PZT, Pb(Zr_{1-y},Ti_{y})O₃ in which 0<y<1] which is a PbZrO₃/PbTiO₃ solid solution having a perovskite structure, and PZT compounds such as PLZT which is a metal oxide obtained by adding La to PZT and PNZT which is a metal oxide obtained by adding Nb to PZT.

For obtaining the capacitor layer, in a step after the formation of a high-dielectric-constant thin film or a ferroelectric thin film, the high-dielectric-constant thin film or the ferroelectric thin film can be patterned. There are some cases where the patterning of the high-dielectric-constant thin film or the ferroelectric thin film is not required. The high-dielectric-constant thin film or the ferroelectric thin film can formed by a method suitable for a material forming the high-dielectric-constant thin film or the ferroelectric thin film, such as an MOCVD method, a pulse laser abrasion method, a sputtering method or a sol-gel method. The high-dielectric-constant thin film or the ferroelectric thin film may be patterned, for example, by an anisotropic ion etching (RIE) method.

In the semiconductor memory device of the present invention including preferred embodiments, examples of the material for constituting the upper electrode include Ir, IrO_{2-X}, SrIrO₃, Ru, RuO_{2-X}SrRuO₃, Pt, Pt/IrO_{2-X}, Pt/RuO_{2-X}, Pd, a Pt/Ti stacked structure, a Pt/Ta stacked structure, a Pt/Ti/Ta stacked structure, La_{0.5}Sr_{0.5}CoO₃(LSCO), a Pt/LSCO stacked structure and YBa₂Cu₃O₇. The value of the above “X” is 0≦X≦2. In each of the above stacked structure, a material described before “/” constitutes an upper layer, and a material after “/” constitutes a lower layer.

For forming the adhesion layer, the lower electrode or the upper electrode, in a step after the formation of the adhesion layer, a lower electrode material layer or an upper electrode material layer, the adhesion layer, the lower electrode material layer or the upper electrode material layer can be patterned. The adhesion layer, the lower electrode material layer or the upper electrode material layer can be formed by a method suitable for a material for the formation of the adhesion layer, the lower electrode material layer or the upper electrode material layer, such as a sputtering method, a reactive sputtering method, an electron beam deposition method, an MOCVD method, a pulse laser abrasion method, or a plating method such as an electric plating method and/or an electroless plating method. Further, the adhesion layer, the lower electrode material layer or the upper electrode material layer can be patterned, for example, by an ion milling method or an RIE method. For a capacitor member having some structure, the adhesion layer and the lower electrode material layer can be patterned by a chemical/mechanical polishing method (CMP method).

In the semiconductor memory device of the present invention including preferred embodiments, examples of the material for constituting the insulating interlayer and the insulating layer include silicon oxide (SiO₂), silicon nitride (SiN), SiON, SOG, NSG, BPSG, PSG, BSG and LTO. The insulating interlayer and the insulating layer may have a single-layered or multi-layered structure of such material(s).

The transistor can be constituted of any one of known MIS type FET and MOS type FET.

The contact plug can be constituted, for example, of polycrystalline silicon containing an impurity, a refractory metal such as tungsten (W) or a compound thereof. In some embodiments, the material forming the contact plug and the material forming the diffusion barrier layer may be the same. In this case, the contact plug and the diffusion barrier layer are not distinguishable. That is, the contact plug has a function as a diffusion barrier layer. Such a structure is also included in the semiconductor memory device of the present invention.

In the semiconductor memory device of the present invention, the adhesion layer is formed at least between the lower electrode and the diffusion barrier layer, and the composition of the adhesion layer is defined, so that the adhesion of the lower electrode can be improved and that peeling of the lower electrode particularly during heat treatment can be reliably prevented.

### BRIEF DESCRIPTION OF THE DRAWINGS

The present invention will be explained on the basis of Examples with reference to drawings hereinafter.

FIGS. 1A and 1B are schematic partial cross-sectional views of a semiconductor substrate, etc., for explaining a method for producing a semiconductor memory device in Example 1.

FIGS. 2A and 2B, following FIG. 1B, are schematic partial cross-sectional views of the semiconductor substrate, etc., for explaining the method for producing the semiconductor memory device in Example 1.

FIGS. 3A and 3B, following FIG. 2B, are schematic partial cross-sectional views of the semiconductor substrate, etc., for explaining the method for producing the semiconductor memory device in Example 1.

FIG. 4 is an equivalent circuit diagram of the semiconductor memory device in Example 1.

FIGS. 5A and 5B are schematic partial cross-sectional views of a semiconductor substrate, etc., for explaining a method for producing a semiconductor memory device in Example 2.

FIGS. 6A and 6B, following FIG. 5B, are schematic partial cross-sectional views of the semiconductor substrate, etc., for explaining the method for producing the semiconductor memory device in Example 2.

FIGS. 7A and 7B, following FIG. 6B, are schematic partial cross-sectional views of the semiconductor substrate, etc., for explaining the method for producing the semiconductor memory device in Example 2.

FIG. 8 is an equivalent circuit diagram of a variant of the semiconductor memory device of the present invention.

FIG. 9 is a schematic partial cross-sectional view of the semiconductor memory device whose equivalent circuit diagram is shown in FIG. 8.

FIG. 10 is a schematic partial cross-sectional view of a variant of the semiconductor memory device of the present invention.

FIG. 11 is a P-E hysteresis loop diagram of a ferroelectric material.

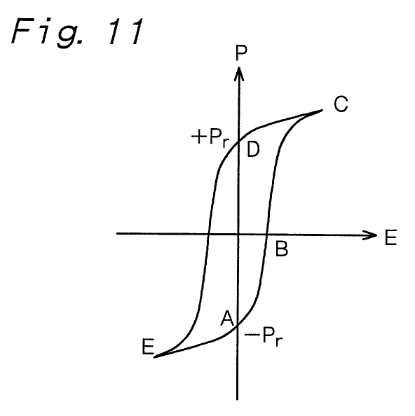

### DESCRIPTION OF THE PREFERRED EMBODIMENTS

### EXAMPLE 1

Example 1 is concerned with a semiconductor memory device constituted of a ferroelectric nonvolatile semiconductor memory device (to be sometimes referred to as “nonvolatile memory” hereinafter).

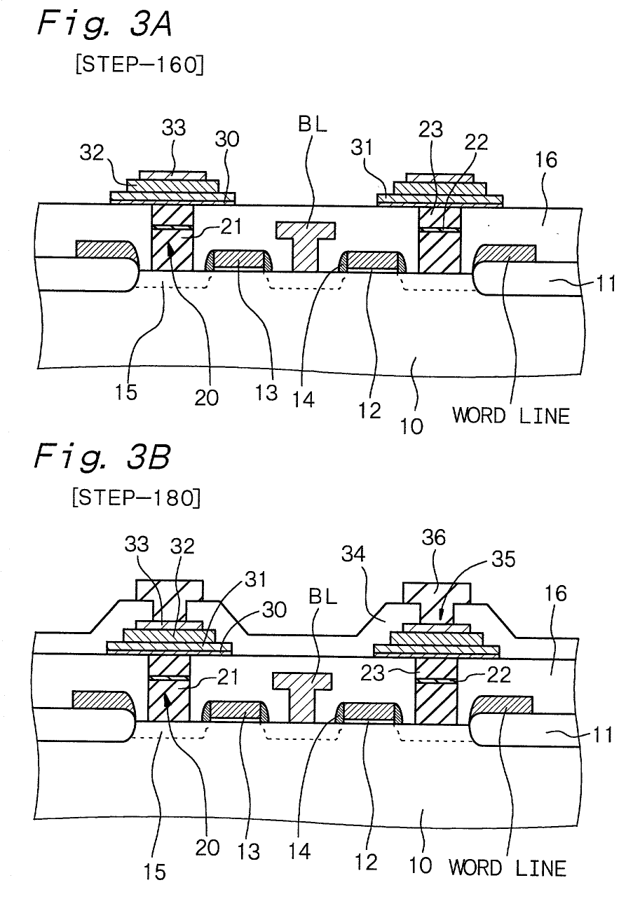

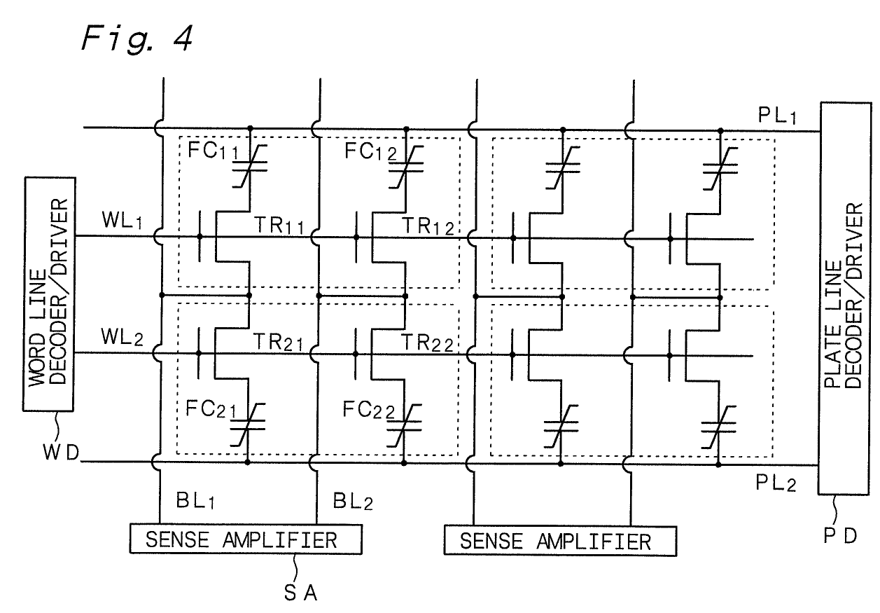

FIG. 3B shows a schematic partial cross-sectional view of the nonvolatile memory of Example 1, and FIG. 4 shows an equivalent circuit diagram thereof. The nonvolatile memory has a so-called stacked capacitor structure, and comprises a transistor, a capacitor member, a contact plug 21, a diffusion barrier layer 23 and an adhesion layer 30. The transistor comprises a gate electrode 13 formed on a gate insulating layer 12 formed on a semiconductor substrate 10, a gate-sidewall 14, and source/drain regions 15 formed in the semiconductor substrate 10. The transistor is surround by a device insulation region 11 formed in the semiconductor substrate 10. The device insulation region 11 has a LOCOS structure or a trench structure, or has a combination of a LOCOS structure and a trench structure.

The capacitor member is formed on an insulating interlayer 16 covering the transistor, and comprises a lower electrode 31, a capacitor layer 32 formed of a ferroelectric material and an upper electrode 33. The capacitor layer 32 is sandwiched between the lower electrode 31 and the upper electrode 33. The lower electrode 31 formed on the insulating interlayer 16 and one source/drain region 15 of the transistor are electrically connected with each other with the contact plug 21 formed in an opening portion 20 made in the insulating interlayer 16. The diffusion barrier layer 23 is formed in that portion of the opening portion 20 which is between the lower electrode 31 and the contact plug 21. That is, the side wall of the diffusion barrier layer 23 is surrounded by the insulating interlayer 16. The adhesion layer 30 is formed between the lower electrode 31 and the diffusion barrier layer 23 and between the lower electrode 31 and the insulating interlayer 16.

The contact plug 21 is formed of polycrystalline silicon containing an impurity, and the diffusion barrier layer 23 is formed of TiN. The lower electrode 31 and the upper electrode 33 are formed of iridium (Ir).

The adhesion layer 30 consists of an alloy that contains a noble metal as a main component, and further contains, as a component, a metal element that differs from any one of the noble metal element, an alkali element and an alkaline earth metal element, and that contains no oxygen atom. Specifically, the alloy contains, as a main component, iridium (Ir) that is an element of the platinum group and contains 15 atomic % of hafnium (Hf) as a metal element that differs from any one of the noble metal element, an alkali element and an alkaline earth metal element.

The nonvolatile memory of Example 1 works on the basis of a pair of nonvolatile memories as shown in the equivalent circuit diagram of FIG. 4. In FIG. 4, each pair of the nonvolatile memories is surrounded by a dotted line. Each nonvolatile memory comprises, for example, a transistor (transistor for selection) TR₁₁ or TR₁₂ and a capacitor member (memory cell) FC₁₁ or FC₁₂. Complement data is written into each nonvolatile memory to store 1 bit. In FIG. 4, symbol “WL” stands for a word line, symbol “BL” stands for a bit line, and symbol “PL” stands for a plate line. When a pair of nonvolatile memories are taken, the word line WL₁ is connected to a word line decoder/driver WD. Further, the bit lines BL₁ and BL₂ are connected to a sense amplifier SA, and the plate line PL₁ is connected to a plate line decoder/driver PD.

When data stored in the nonvolatile memories having the above structure is read out, the word line WL₁ is selected, and further, the plate line PL₁ is driven, whereby complement data appears as a voltage (bit line potential) between a pair of the bit lines BL₁ and BL₂ from a pair of the capacitor members FC₁₁ and FC₁₂ through the transistors for selection TR₁₁ and TR₁₂. The above voltage (bit line potential) between a pair of the bit lines BL₁ and BL₂ is detected with the sense amplifier SA.

The above constitution and operation of the nonvolatile memory are shown as an example and may be modified as required.

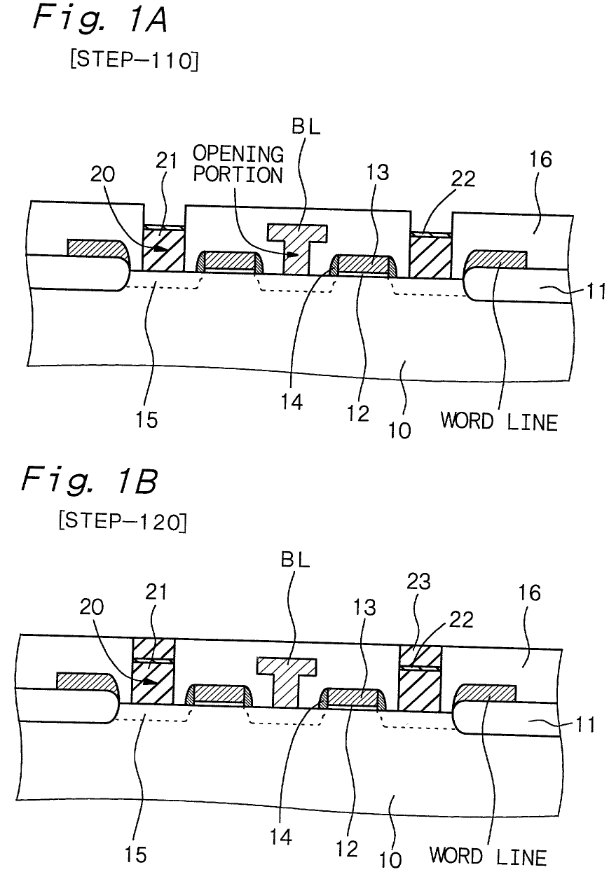

The nonvolatile memory of Example 1 will be explained hereinafter with reference to FIGS. 1A, 1B, 2A, 2B, 3A and 3B showing schematic partial cross-sectional views of the semiconductor substrate and the like.

[Step-100]

The transistor is formed in the semiconductor substrate 10 by a known method.

[Step-110]

Then, an SiO₂ layer is formed on the entire surface by a CVD method, the opening portion is made for electrically connecting other source/drain region 15 and the bit line BL, the bit line BL is formed, and an SiN layer is formed on the entire surface. In explanations to be described hereinafter, the SiO₂ layer and the SiN layer will be together referred to as an insulating interlayer 16. The insulating interlayer 16 formed had a thickness of 1.2 μm. The bit line BL is extending leftward and rightward such that it will not be in contact with the contact plug 21. Then, the insulating interlayer 16 is polished by a chemical/mechanical polishing method (CMP method), to flatten the surface of the insulating interlayer 16. The flattened insulating interlayer 16 had a thickness of 0.85 μm. Then, the opening portion 20 is made in the insulating interlayer 16 above one source/drain region 15 by lithography and a dry etching technique. Then, a 0.6 μm thick polycrystalline silicon layer containing an impurity is deposited in the opening portion 20 and on the insulating interlayer 16 by a CVD method, and heat-treated at 850° C. for 30 minutes to activate the impurity contained in the polycrystalline silicon layer. Then, the polycrystalline silicon layer on the insulating interlayer 16 is removed by a CMP method. Further, the polycrystalline silicon layer in the opening portion 20 is 0.15 μm etched back by a dry etching technique, and then a silicide layer 22 is formed on the top surface of the polycrystalline silicon layer.

Specifically, a 20 nm thick cobalt (Co) film and a 10 nm thick titanium (Ti) film are consecutively formed on the entire surface by a DC magnetron sputtering method, and then these layers are subjected to RTA (rapid thermal annealing) treatment in a nitrogen gas atmosphere at 550° C. for 30 seconds, to form the silicide layer 22, which is made of cobalt silicide. Then, unreacted titanium film and titanium nitride on the insulating interlayer 16 are removed with am aqueous mixture of ammonia and hydrogen peroxide, and unreacted cobalt film is further removed with an aqueous mixture of sulfuric acid and hydrogen peroxide. Then, RTA treatment is carried out in a nitrogen gas atmosphere at 700° C. for 30 seconds, to stabilize the silicide layer 22. In this manner, the contact plug 21 made of polycrystalline silicon and the silicide layer 22 formed on the top surface of the contact plug 21 can be obtained in the opening portion 20 made in the insulating interlayer 16. FIG. 1A shows the thus-obtained state. The silicide layer 22 is formed for decreasing the contact resistance.

[Step-120]

Then, a 0.3 μm thick TiN layer is formed in the opening portion 20 and on the insulating interlayer 16 by a DC magnetron sputtering method, TiN layer on the insulating interlayer 16 is removed by a CMP method, and heat treatment is carried out in a nitrogen gas atmosphere at 600° C. for 30 minutes, whereby an approximately 0.15 μm thick diffusion barrier layer 23 can be formed on the contact plug 21 in the opening portion 20. The side wall of the diffusion barrier layer 23 is surrounded by the insulating interlayer 16. FIG. 1B shows the thus-obtained state. The thickness of the diffusion barrier layer 23 shall not be limited to the above, and it can be further decreased as long as it has barrier properties. The method of forming the diffusion barrier layer shall not be limited to the sputtering method, and it can be formed, for example, by a CVD method.

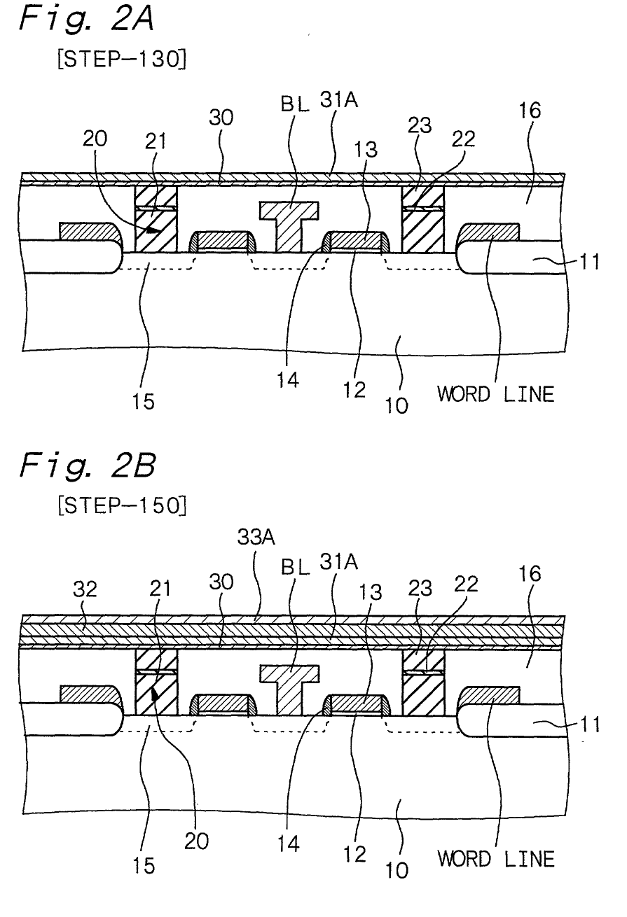

There may be employed a constitution in which the top surface of the contact plug 21 is nearly at a level at which the surface of the insulating interlayer 16 is present, and the diffusion barrier layer 23 is formed on the contact plug 21. That is, there may be employed a structure in which the side wall of the diffusion barrier layer is exposed. However, when a capacitor layer made of a ferroelectric material is heat-treated in an oxygen gas atmosphere for crystallization or recovery from deterioration of properties in a process to come later, the diffusion barrier layer may be oxidized in the exposed side wall, which may lead to an expansion and peeling thereof or a conduction failure. It is therefore preferred to employ a structure in which the side wall of the diffusion barrier layer 23 is surrounded by the insulating interlayer 16.

[Step-130]Then, as an adhesion layer 30, a 20 nm thick iridium (Ir) layer containing 15 atomic % of hafnium (Hf) is formed on the entire surface by a DC magnetron sputtering method under a condition shown in the following Table 1, and a 0.15 μm thick lower electrode material layer 31A made of iridium (Ir) is formed thereon by a DC magnetron sputtering method under a condition shown in the following Table 2 (see FIG. 2A).

TABLE 1
Formation of adhesion layer

| | |
|---|---|
| Target | Ir (containing 15 |
| | atomic % of Hf) |
| Process gas | Ar |
| Pressure | 0.4 Pa |
| Power | 1 kW |
| Forming temperature | 400° C. |

TABLE 2
Formation of lower electrode material layer

| | |
|---|---|
| Target | Ir |
| Process gas | Ar |
| Pressure | 0.4 Pa |
| Power | 2 kW |
| Forming temperature | 400° C. |

[Step-140]

Then, a capacitor layer 32 made of SrBi₂Ta₂O₉ is formed on the lower electrode material layer 31A by a sol-gel method. Specifically, a precursor solution for forming the capacitor layer 32 was applied to the entire surface by a spin-on method (number of spinning: 3000 rpm, spinning time period: 20 seconds), the semiconductor substrate was placed on a hot plate at 250° C. in atmosphere for 7 minutes, to completely remove a solvent, then, RTA treatment was carried out at 750° C. for 30 seconds in an oxygen gas atmosphere at 1 atom for crystallization of the ferroelectric material, and further, heat treatment was carried out at 750° C. in an oxygen atmosphere at 1 atom for 30 minutes. These procedures were repeated three times, to give the capacitor layer 32 having a thickness of 0.1 μm. The above precursor solution was a mixture which was prepared from tantalum ethoxide [Ta(OC₂H₅)₅], bismuth-2-ethylhexanoate [Bi(CH₃(CH₂)₃CH(C₂H₅)COO)₃] and strontium-2-ethylhexanoate [Sr(CH₃(CH₂)₃CH(C₂H₅)COO)₂] and had an Sr/Bi/Ta metal element ratio of 0.8/2.2/2.0. The composition and the raw materials for the precursor solution shall not be limited to these.

[Step-150]

Then, a 0.1 μm thick upper electrode material layer 33A made of iridium (Ir) is formed on the capacitor layer 32 by a DC magnetron sputtering method under the condition shown in Table 2 (see FIG. 2B).

[Step-160]

The upper electrode material layer 33A, the capacitor layer 32, the lower electrode material layer 31A and the adhesion layer 30 are respectively patterned by lithography and a dry etching technique, to obtain a capacitor member comprising the lower electrode 31, the capacitor layer 32 and the upper electrode 33 (see FIG. 3A). The upper electrode material layer 33A, the capacitor layer 32, the lower electrode material layer 31A and the adhesion layer 30 may be together patterned with a hard mask. The adhesion layer 30 comes to be formed between the lower electrode 31 and the diffusion barrier layer 23 and between the lower electrode 31 and the insulating interlayer 16.

[Step-170]

Then, the capacitor layer 32 is heat-treated in an oxygen gas atmosphere at 700° C. for 30 minutes for recovery thereof from property deterioration. Since the side wall of the diffusion barrier layer 23 is surrounded by the insulating interlayer 16, the diffusion barrier layer 23 is not at all oxidized in any case, so that the problem of peeling or conduction failure is not at all caused. In a structure where the side wall of the diffusion barrier layer 23 is exposed, it is required to carry out the heat treatment in an inert gas atmosphere, and it is required to carry out the heat treatment at a temperature of 650° C. or lower, so that the recovery of the capacitor layer from property deterioration is insufficient in some cases.

[Step-180]

A 0.3 μm thick insulation layer 34 made of SiO₂ is formed on the entire surface by a CVD method, and an opening portion 35 is made in the insulation layer 34 above the upper electrode 33. Then, a 20 nm thick Ti film and a 20 nm thick TiN film are consecutively formed in the opening portion 35 and on the insulation layer 34 by a DC magnetron sputtering method. Further, a 0.6 μm thick Al −1% Si film is formed on the TiN film, and then the Al −1% Si film, the TiN film and the Ti film are patterned to complete a wiring (plate line) 36 (see FIG. 3B). FIG. 3B omits showing of the Ti film and the TiN film. In this manner, the nonvolatile memory can be obtained.

When no adhesion layer was formed, peeling was found in the lower electrode 31 in the step of the heat treatment in [Step-140]. When the adhesion layer 30 was formed, no peeling was found in the lower electrode 31. When an adhesion layer was constituted of an iridium (Ir) layer containing over 25 atomic % of hafnium (Hf) and a nonvolatile memory was prepared in the same manner as above, peeling was locally found in the lower electrode. This is presumably because the segregation of an inter-metallic compound of Ir₃Hf, etc., had an influence.

Further, the diffusion barrier layer was constituted of a 0.1 μm thick TiN film, the lower electrode was constituted of a 0.15 μm thick iridium film, the adhesion layer was constituted of an iridium (Ir) layer containing 15 atomic % of hafnium (Hf), and the thickness of the adhesion layer was changed from 5 nm to 100 nm. As a result, no peeling of the adhesion layer was found when the adhesion layer had a thickness of 50 nm or less. When the adhesion layer had a thickness of 100 nm, peeling was locally found. It is assumed that this was caused by a stress of the adhesion layer itself.

A resistance between the contact plug 21 and the lower electrode 31 was measured by a known Kelvin's four-point probe method and also measured using a contact plug chain connecting tens to thousands of the contact plugs in series. In both cases, a linear I-V characteristic was shown, and the contact plugs having a diameter of 0.4 μm each showed a resistance value of approximately 300 Ω. The above data shows that the lower electrode in the semiconductor memory device of the present invention has excellent heat resistance. Further, the capacitor layer 32 made of the ferroelectric material also showed an excellent residual polarization value of 20 μC/cm².

Further, in the same manner as in the above, there were prepared nonvolatile memories respectively having an adhesion layer containing not more than 50 atomic % of aluminum (Al), an adhesion layer containing not more than 25 atomic % of titanium (Ti), an adhesion layer containing not more than 25 atomic % of vanadium (V), an adhesion layer containing not more than 25 atomic % of zirconium (Zr), an adhesion layer containing not more than 25 atomic % of niobium (Nb), an adhesion layer containing not more than 25 atomic % of molybdenum (Mo), an adhesion layer containing not more than 25 atomic % of tantalum (Ta) and an adhesion layer containing not more than 20 atomic % of tungsten (W). When the thus-obtained nonvolatile memories were tested in the same manner as above, there were obtained results that were similar to the results of the adhesion layer containing not more than 25 atomic % of hafnium (Hf).

### EXAMPLE 2

Example 2 is concerned with a variant of the semiconductor memory device of Example 1. In the nonvolatile memory of Example 2, the lower electrode has a so-called damascene structure.

The damascene structure generally refers to a wiring structure formed by a method in which a recess corresponding to a wiring pattern is formed in an insulating layer, a wiring material layer is formed in the recess and on the insulating layer, and a wiring material layer on the insulating layer is removed by a CMP method so that a wiring material layer is embedded in the recess. In existing technologies of manufacturing semiconductor devices, improvements are being made in microfabrication and are making it difficult to form a wiring by a combination of conventional lithography and dry etching techniques alone, so that the damascene structure is, among technologies, attracting attention as a leading method of forming a wiring. In particular, when a noble metal material that has low reactivity is used for an electrode like the present invention, microfabrication by dry etching is very difficult, and the damascene structure is suitable for the microfabrication.

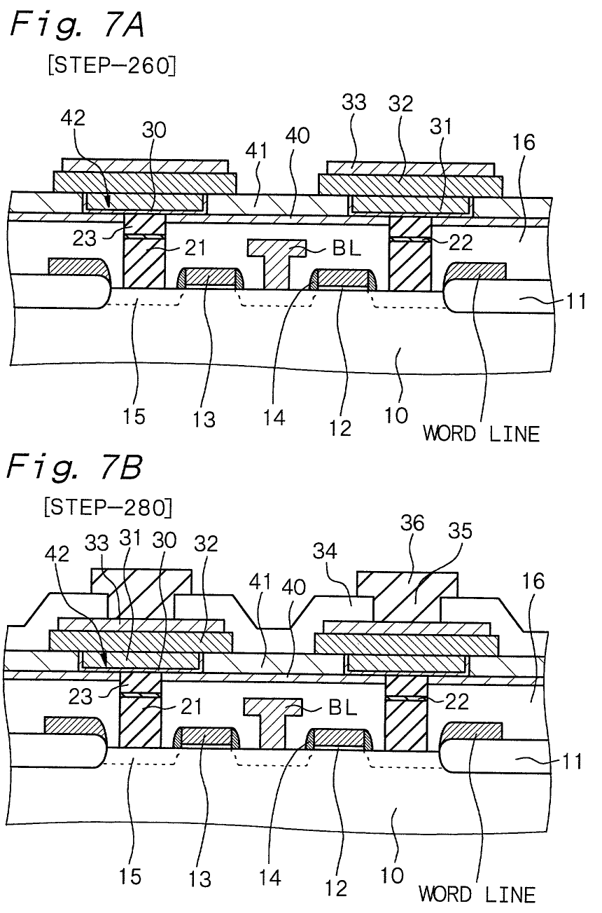

That is, in the nonvolatile memory of Example 2, as FIG. 7B shows a schematic partial cross-sectional view thereof, an insulating layer 41 is formed on an insulating interlayer 16. A recess 42 is formed in the insulating layer 41. At least a diffusion barrier layer 23 is exposed in the bottom of the recess 42. And, an adhesion layer 30 and a lower electrode 31 are formed in the recess 42.

Other structures of the nonvolatile memory of Example 2 are the same as those of the nonvolatile memory explained in Example 1, so that a detailed explanation thereof is omitted.

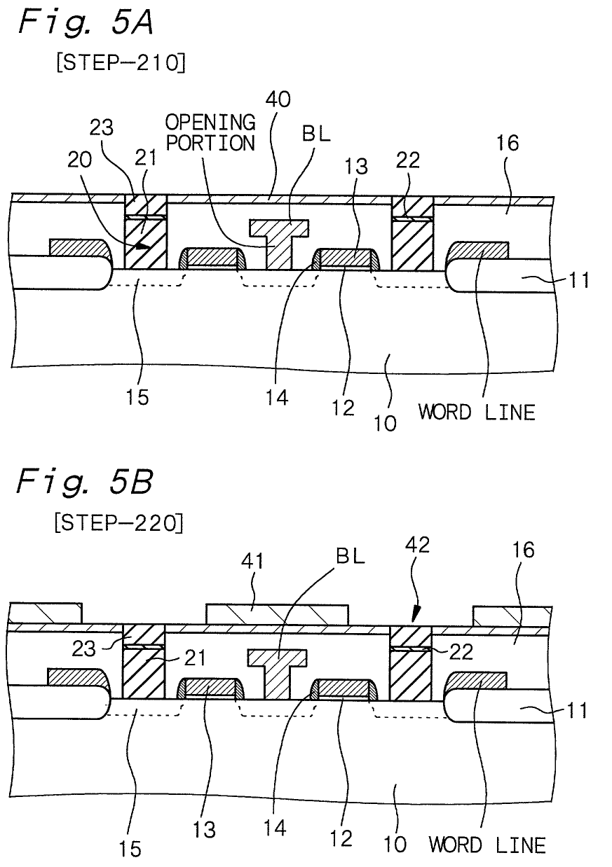

The method of manufacturing the nonvolatile memory of Example 2 will be explained with reference to FIGS. 5A, 5B, 6A, 6B, 7A and 7B showing schematic partial cross-sectional views of a semiconductor substrate and the like.

[Step-200]

First, the transistor is formed in a semiconductor substrate 10 by a known method.

[Step-210]

Then, the bit line BL is formed, the insulating interlayer 16 is formed, and the surface of the insulating interlayer 16 is flattened, in the same manner as in [Step-110] in Example 1. Then, a 50 nm thick etching-stop layer 40 made of SiN is formed on the entire surface by a CVD method. Then, the contact plug 21 made of a polycrystalline silicon layer is formed in the opening portion 20, and a silicide layer 22 is formed, in the same manner as in [Step-110] in Example 1. Further, the diffusion barrier layer 23 is formed on the contact plug 21 in the opening portion 20 in the same manner as in [Step-120] in Example 1. The thus-obtained state is shown in FIG. 5A. The etching-stop layer 40 shows almost no difference in thickness at this point of time, since it has durability against polishing the polycrystalline silicon layer by a CMP method, etching back of the polycrystalline silicon layer and polishing of the diffusion barrier layer by a CMP method.

[Step-220]

Then, a 0.2 μm thick insulating layer 41 made of SiO₂ is formed on the entire surface by a CVD method, and the recess 42 is formed in the insulating layer 41 by lithography and a dry etching technique (see FIG. 5B). When the insulating layer 41 is dry-etched, the etching-stop layer 40 made of SiN and the diffusion barrier layer 23 made of TiN work as etching stoppers.

[Step-230]

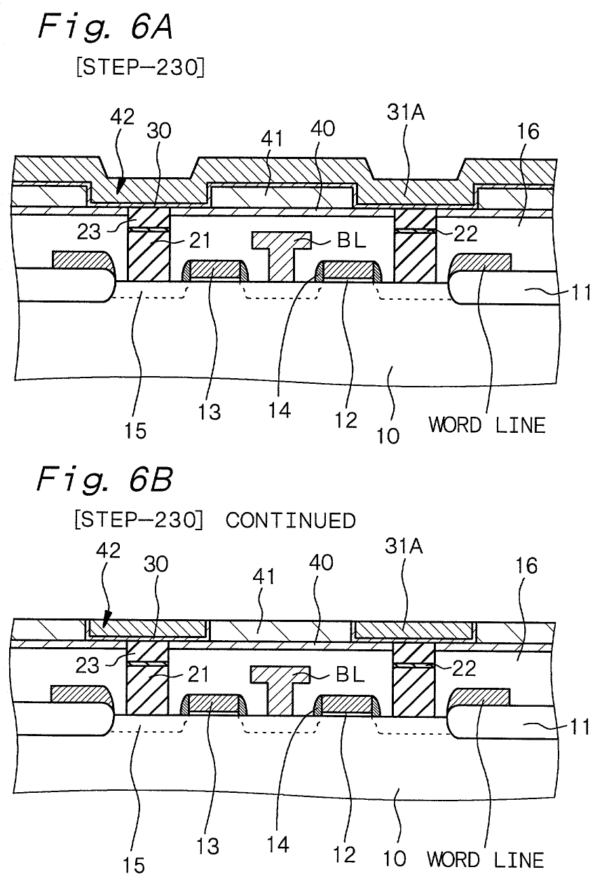

Then, as an adhesion layer 30, a 20 nm thick iridium (Ir) layer containing 15 atomic % of hafnium (Hf) is formed on the entire surface by a DC magnetron sputtering method, and a 0.3 μm thick lower electrode material layer 31A made of iridium (Ir) is formed thereon by a DC magnetron sputtering method (see FIG. 6A). Then, the adhesion layer 30 and the lower electrode material layer 31A on the insulating layer 41 are removed by a CMP method. In this manner, there can be obtained a structure in which the adhesion layer 30 and the lower electrode 31 are embedded in the recess 42 as shown in FIG. 6B.

[Step-240]

Then, the capacitor layer 32 made of SrBi₂Ta₂O₉ is formed on the entire surface (specifically, on the insulating layer 41 and on the lower electrode 31) by a sol-gel method. Specifically, a precursor solution for forming the capacitor layer 32 was applied to the entire surface by a spin-on method (number of spinning: 3000 rpm, spinning time period: 20 seconds), the semiconductor substrate was placed on a hot plate at 250° C. in atmosphere for 7 minutes, to completely remove a solvent, then, RTA treatment was carried out at 750° C. for 30 seconds in an oxygen gas atmosphere at 1 atom for crystallization of the ferroelectric material, and further, heat treatment was carried out at 750° C. in an oxygen atmosphere at 1 atom for 30 minutes. These procedures were repeated three times, to give the capacitor layer 32 having a thickness of 0.1 μm.

[Step-250]

Then, a 0.1 μm thick upper electrode material layer 33A made of iridium (Ir) is formed on the capacitor layer 32 by a DC magnetron sputtering method.

[Step-260]

Then, the upper electrode material layer 33A and the capacitor layer 32 are patterned by lithography and a dry etching technique, to obtain a capacitor member comprising the lower electrode 31, the capacitor layer 32 and the upper electrode 33 (see FIG. 7A). The upper electrode material layer 33A and the capacitor layer 32 may be together patterned with a hard mask.

[Step-270]

Then, the capacitor layer 32 is heat-treated in an oxygen gas atmosphere at 700° C. for 30 minutes for recovery thereof from property deterioration in the same manner as in [Step-170] in Example 1.

[Step-280]

Then, the insulation layer 34 is formed on the entire surface, and, further, a wiring (plate line) 36 is formed, in the same manner as in [Step-180] in Example 1 (see FIG. 7B). FIG. 7B omits showing of the Ti film and the TiN film. In this manner, a nonvolatile memory can be obtained.

When no adhesion layer was formed, peeling was found in the lower electrode 31 in the heat treatment step in [Step-240]. When the adhesion layer 30 was formed, no peeling was found in the lower electrode 31. When an adhesion layer was constituted of an iridium (Ir) layer containing over 25 atomic % of hafnium (Hf) and a nonvolatile memory was prepared in the same manner as above, peeling was locally found in the lower electrode.

A resistance between the contact plug 21 and the lower electrode 31 was measured by a known Kelvin's four-point probe method and also measured using a contact plug chain connecting tens to thousands of the contact plugs in series. In both cases, a linear I-V characteristic was shown like Example 1, and the contact plugs having a diameter of 0.4 μm each showed a resistance value of approximately 300 Ω. The above data shows that the lower electrode in the semiconductor memory device of the present invention has excellent heat resistance. Further, the capacitor layer 32 made of the ferroelectric material also showed an excellent residual polarization value of 20 μC/cm².

Further, in the same manner as in the above, there were prepared nonvolatile memories respectively having an adhesion layer containing not more than 50 atomic % of aluminum (Al), an adhesion layer containing not more than 25 atomic % of titanium (Ti), an adhesion layer containing not more than 25 atomic % of vanadium (V), an adhesion layer containing not more than 25 atomic % of zirconium (Zr), an adhesion layer containing not more than 25 atomic % of niobium (Nb), an adhesion layer containing not more than 25 atomic % of molybdenum (Mo), an adhesion layer containing not more than 25 atomic % of tantalum (Ta) and an adhesion layer containing not more than 20 atomic % of tungsten (W). When the thus-obtained nonvolatile memories were tested in the same manner as above, there were obtained results that were similar to the results of the adhesion layer containing not more than 25 atomic % of hafnium (Hf).

The present invention has been explained on the basis of Examples hereinabove, while the present invention shall not be limited thereto. In Examples, the nonvolatile memory constituted of one transistor and one capacitor member has been explained as an example, while the nonvolatile memory shall not be structurally limited thereto.

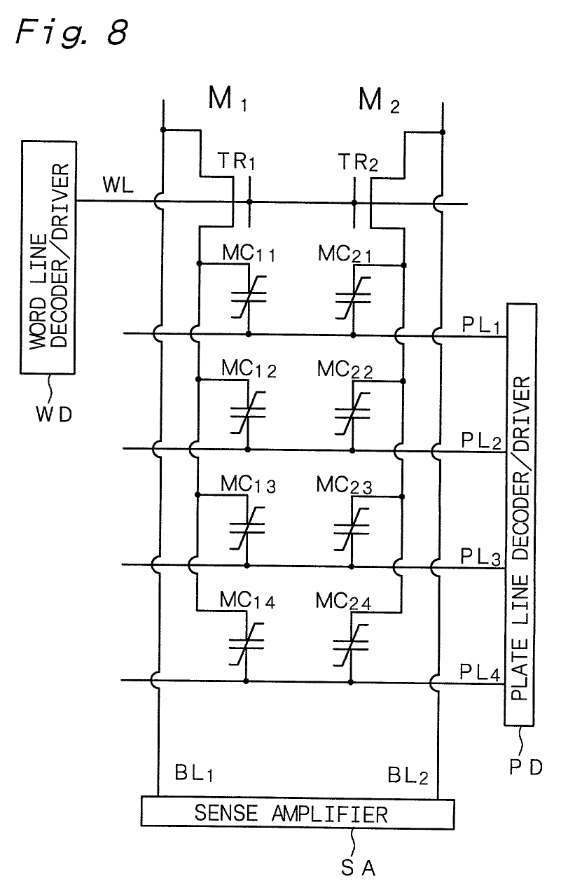

For example, the semiconductor memory device of the present invention can be applied to a nonvolatile memory having a structure disclosed in JP-A-9-121032. As an equivalent circuit diagram is shown in FIG. 8, the nonvolatile memory disclosed in the above JP-A-9-121023 comprises a nonvolatile memory M₁ constituted of a plurality of capacitor members (to be referred to as “memory cells” hereinafter) (for example, M=4), an end of each capacitor member MC_{1M} being connected to one end of one transistor (to be referred to as “transistor for selection” hereinafter) TR₁ in parallel, and a nonvolatile memory M₂ constituted of a plurality of memory cells MC_{2M}, an end of each capacitor member MC_{2M} being connected to one end of another transistor for selection TR₂ in parallel. And, a memory cell MC_{1M} and a memory cell MC_{2M} form a pair. The other end of the transistor for selection TR₁ is connected to a bit line BL₁, and the other end of the transistor for selection TR₂ is connected to a bit line BL₂. The bit lines BL₁ and BL₂ forming a pair are connected to a sense amplifier SA. The other end of each of the memory cells MC₁ₘ and MC₂ₘ (m=1, 2 . . . M) is connected to a common plate line PLₘ, and the plate line PLₘ is connected to a plate line decoder/driver PD. Further, a word line WL is connected to a word line decoder/driver WD.

Complement data is stored in a pair of the memory cells MC₁ₘ and MC₂ₘ (m=1, 2 . . . M). When data stored in the memory cell MC₁ₖ and MC₂ₖ (in this embodiment, k is one of 1, 2, 3 and 4) is read out, the word line WL is selected, and in a state where a voltage of (½) V_{cc} is applied to the plate line PLₘ (m≠k), the plate line PLₖ is driven. The above V_{cc} is, for example, a power source voltage. As a result, the complement data appears as a voltage (bit line potential) between a pair of the bit lines BL₁ and BL₂ from a pair of the memory cells MC₁ₖ and MC₂ₖ through the transistors for selection TR₁ and TR₂. The above voltage (bit line potential) between a pair of the bit lines BL₁ and BL₂ is detected with the sense amplifier SA. Alternatively, data can be read out from each of the memory cells MC₁ₘ and MC₂ₘ by applying a reference voltage to one of the bit lines BL₁ and BL₂.

A pair of the transistors for selection TR₁ and TR₂ in a pair of the nonvolatile memories occupies a region surrounded by the word line WL and a pair of the bit lines BL₁ and BL₂. If the word line and the bit lines are arranged at a smallest pitch, therefore, the minimum area of a pair of the transistors for selection TR₁ and TR₂ in a pair of the nonvolatile memories is 8F² when a process minimum dimension is taken as F. However, a pair of the transistors for selection TR₁ and TR₂ are shared by pairs of memory cells MC₁ₘ and MC₂ₘ (m=1, 2 . . . M), so that the number of the transistors for selection TR₁ and TR₂ per bit can be decreased. Further, the layout of the word line WL is moderate. Therefore, the nonvolatile memory can be easily decreased in size. Concerning peripheral circuits, further, M bits can be selected with one word line decoder/driver WD and M plate line decoder/drivers PD. When the above constitution is employed, therefore, a layout close to a cell area of 8F² can be realized, and a chip size almost equivalent to DRAM can be realized.

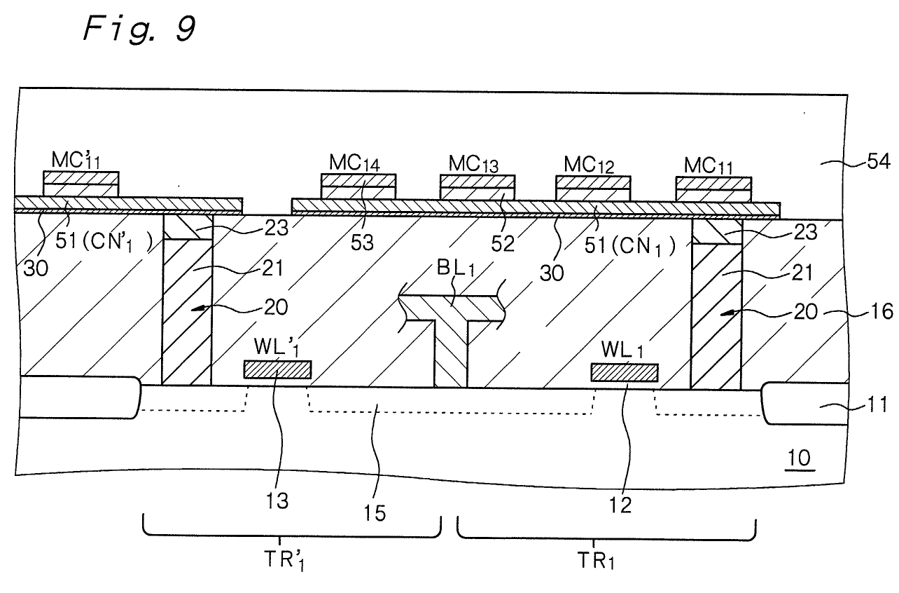

FIG. 9 shows a schematic partial cross-sectional view of such a nonvolatile memory. In the equivalent circuit diagram of FIG. 8, two nonvolatile memories M₁ and M₂ are shown. These nonvolatile memories have identical circuits and identical structures and formed side by side in the direction perpendicular to the paper surface of FIG. 9. In the following explanation, the nonvolatile memory M₁ will be explained. FIG. 9 shows the transistor for selection TR₁ and the memory cells MC₁ₘ and also shows a transistor for selection TR′₁ contiguous in the extending direction of the bit line BL₁ and part of memory cells MC′₁ₘ. The bit line BL₁ in the memory cells MC₁ₘ, MC′₁ₘ . . . which are contiguous in the extending direction of the bit line BL₁ is common.

Each of memory cells (capacitor members) MC₁ₘ constituting the nonvolatile memory M₁ comprises a lower electrode 51, a capacitor layer 52 formed of a ferroelectric material and an upper electrode 53. In the nonvolatile memory M₁, the lower electrode 51 of the memory cells is common. The common lower electrode will be referred to as common node CN₁ for convenience. The common lower electrode 51 (common node CN₁) in the nonvolatile memory M₁ is connected to the bit line BL₁ through the transistor for selection TR₁. Further, the common lower electrode (common node) in the nonvolatile memory M₂ is connected to the bit line BL₂ through the transistor for selection TR₂. An adhesion layer 30 is formed between the lower electrode 51 (common node CN₁) and an insulating interlayer 16.

Each memory cell (capacitor member) MC₁ₘ is formed above a semiconductor substrate 10 through the insulating interlayer 16. A device insulation region 11 is formed in the semiconductor substrate 10. Further, the transistor for selection TR₁ comprises a gate electrode 13, a gate insulating layer 12 and source/drain regions 15. And, the other source/drain region 15 of the transistor for selection TR₁ is connected to the bit line BL₁ through a contact hole. Further, one source/drain region 15 of the transistor for selection TR₁ is connected to the common node CN₁ through a contact plug 21 formed in an opening portion 20 made in the insulating interlayer 16, a silicide layer (not shown) and a diffusion barrier layer 23. Each memory cell MC₁ₘ is covered by an insulation layer 54. The word line WL₁ extends in the direction perpendicular to the paper surface of FIG. 9. The upper electrode 53 is common to memory cells constituting the nonvolatile memory M₂ and being contiguous in the direction perpendicular to the paper surface of FIG. 9, and the upper electrode also works as a plate line PLₘ.

And, 1 bit is stored in each of the memory cells MC₁₁ₘ and MC₁₂ₘ (m=1, 2, 3, 4) as data, or, complement data is stored in a pair of the memory cells MC₁₁ₘ and MC₁₂ₘ. In an actual nonvolatile memory, a set of the above memory units for storing 8 bits or 4 bits are arranged in the form of an array as an access unit.

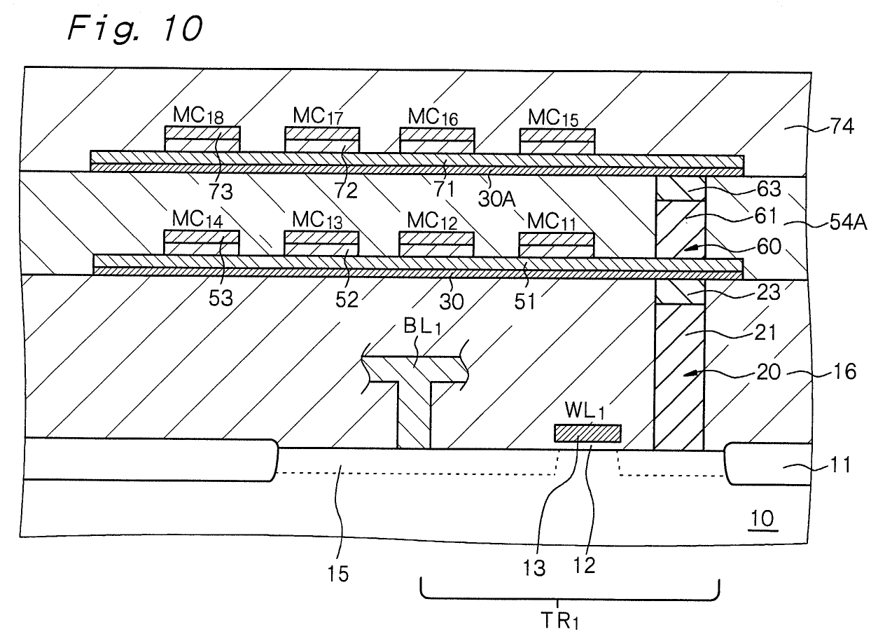

There may be optionally employed a structure in which the memory cells MC_{1M} for constituting the nonvolatile memory M₁ are divided into a plurality of groups and these groups are stacked one on other or another through an insulating interlayer. In this case, the density of integration of the semiconductor memory device can be further improved. FIG. 10 shows an example of such a structure. Memory cells MC₁₁, MC₁₂, MC₁₃ and MC₁₄ of the memory cells MC_{1M} constituting the nonvolatile memory M₁ are formed on an insulating interlayer 16, an insulating interlayer 54A is formed on these memory cells, and memory cell MC₁₅, MC₁₆, MC₁₇ and MC₁₈ are formed on the insulating interlayer 54A. The memory cell MC₁₅, MC₁₆, MC₁₇ and MC₁₈ are covered with an insulation layer 74. Each of the memory cells MC₁₁, MC₁₂, MC₁₃ and MC₁₄ comprises a lower electrode 51, a capacitor layer 52 formed of a ferroelectric material and an upper electrode 53. An adhesion layer 30 is formed between the lower electrode 51 and the insulating interlayer 16. One source/drain region 15 of the transistor for selection TR₁ is connected to the lower electrode 51 that is a common node, through a contact plug 21 formed in an opening portion 20 made in the insulating interlayer 16, a silicide layer (not shown) and a diffusion barrier layer 23. Each of the memory cells MC₁₅, MC₁₆, MC₁₇ and MC₁₈ comprises a lower electrode 71, a capacitor layer 72 made of a ferroelectric material and an upper electrode 73. An adhesion layer 30A is formed between the lower electrode 71 and the insulating interlayer 54A. Further, one source/drain region 15 of the transistor for selection TR₁ is connected to the lower electrode 71 that is a common node, through the contact plug 21, a silicide layer (not shown), the diffusion barrier layer 23, a contact plug 61 formed in an opening portion 60 made in the insulating interlayer 54A, a silicide layer (not shown) and a diffusion barrier layer 63.

Alternatively, the memory cell MC_{1M} for constituting the nonvolatile memory M₁ and the memory cell MC_{2M} for constituting the nonvolatile memory M₂ may be stacked through an insulating interlayer.

Further, the adhesion layers 30 and 30A and the lower electrodes 51 and 71 may have a damascene structure explained in Example 2.

In Examples, the capacitor layer made of a ferroelectric material was formed by a sol-gel method, while the method of forming the capacitor layer shall not be limited to the sol-gel method. For example, the capacitor layer can be formed by an MOCVD method. The following Table 3 shows a condition of forming a ferroelectric thin film made of SrBi₂Ta₂O₉. In Table 3, “thd” stands for tetramethylheptadione. Further, source materials shown in Table 3 were dissolved in a solvent containing tetrahydrofuran (THF) as a main component.

TABLE 3
Formation by MOCVD method

| | |
|---|---|
| Source materials | Sr(thd)₂-tetraglyme |
| | Bi(C₆H₅)₃ |
| | Ta(O-iC₃H₇)₄(thd) |
| Forming temperature | 400-700° C. |
| Process gas | Ar/O₂ = 1000/1000 sccm |
| Forming rate | 5-20 nm/minute |

Alternatively, a ferroelectric thin film made of SrBi₂Ta₂O₉ may be formed on the entire surface by a pulse laser abrasion method or an RF sputtering method. The following Tables show forming conditions in these cases.

TABLE 4
Formation by pulse laser abrasion method

| | |
|---|---|
| Target | SrBi₂Ta₂O₉ |
| Laser | KrF Excimer laser |
| | (wavelength 248 nm, pulse |
| | width 25 n seconds, 5 Hz) |
| Forming temperature | 400-750° C. |
| Oxygen concentration | 3 Pa |

TABLE 5
Formation by RF sputtering method

| | |
|---|---|
| Target | SrBi₂Ta₂O₉ ceramic target |
| RF power | 1.2 W-2.0 W/target |
| | 1 cm² |
| Ambient pressure | 0.2-1.3 Pa |
| Forming temperature | Room temperature-600° C. |
| Process gas | Ar/O₂ flow rate = 2/1-9/1 |

The following Table 6 shows a forming condition of PZT or PLZT by a magnetron sputtering method when the ferroelectric thin film is constituted from PZT or PLZT. Otherwise, the ferroelectric thin film may be formed from PZT or PLZT by a reactive sputtering method, an electron beam deposition method, a sol-gel method or an MOCVD method.

TABLE 6

| | |
|---|---|
| Target | PZT or PLZT |
| Process gas | Ar/O₂ = 90 vol %/10 vol % |
| Pressure | 4 Pa |
| Power | 50 W |
| Forming temperature | 500° C. |

The ferroelectric thin film may be formed from PZT or PLZT by a pulse laser abrasion method. The following Table 7 shows a forming condition in this case.

TABLE 7

| | |
|---|---|
| Target | PZT or PLZT |
| Laser | KrF Excimer laser |
| | (wavelength 248 nm, pulse |
| | width 25 n seconds, 3 Hz) |
| Output energy | 400 mJ (1.1 J/cm²) |
| Forming temperature | 550-600° C. |
| Oxygen concentration | 4-120 Pa |

The capacitor structure of the semiconductor memory device of the present invention can be applied not only to a nonvolatile memory (so-called FERAM) using a ferroelectric thin film but also to a DRAM. In this case, only an unswitched component of dielectric constant of a ferroelectric thin film is utilized. Further, it can be applied to a DRAM using a high-dielectric-constant material such as BaTiO₃ (barium titanate) or (Ba,Sr)TiO₃ (barium-strontium titanate) for a capacitor layer.

According to the present invention, the adhesion layer formed can reliably prevent the lower electrode from peeling off the diffusion barrier layer or the insulating interlayer, so that the heat resistance of the lower electrode against high-temperature heat treatment in an oxygen gas atmosphere can be improved. As a result, a sufficient margin can be provided in the heat treatment for the formation (crystallization) of the capacitor layer made of a high-dielectric-constant material or a ferroelectric material or the recovery of the capacitor layer from property deterioration, and a semiconductor memory device having a so-called stacked capacitor structure can be produced, so that the integration density of the semiconductor memory device can be increased. Further, a semiconductor memory device excellent in properties and reliability can be provided. Furthermore, when a damascene structure is employed as a structure of the lower electrode, far finer microfabrication can be performed.

What is claimed is:

1. A semiconductor memory device comprising;
(A) a transistor,
(B) a capacitor member formed above said transistor through an insulating interlayer, said capacitor member comprising a lower electrode, a capacitor layer formed of a high-dielectric-constant material or a ferroelectric material and an upper electrode,
(C) a contact plug formed in said insulating interlayer, for electrically connecting the lower electrode formed on the insulating interlayer with the transistor, and
(D) a diffusion barrier layer formed between the lower electrode and the contact plug,
said semiconductor memory device further comprising;
(E) an adhesion layer formed at least between the lower electrode and the diffusion barrier layer, and
said adhesion layer consisting of an alloy that contains a noble metal element as a main component, and contains, as a component, a metal element that differs from any one of the noble metal element, an alkali element and an alkaline earth metal element and that contains no oxygen atom.

2. The semiconductor memory device according to claim 1, in which the adhesion layer is formed between the lower electrode and the diffusion barrier layer and between the lower electrode and the insulating interlayer.

3. The semiconductor memory device according to claim 1, in which an insulating layer is formed on the insulating interlayer, the insulating layer has a recess having a bottom where at least the diffusion barrier layer is exposed, and the adhesion layer and the lower electrode are formed in the recess.

4. The semiconductor memory device according to claim 1, in which the diffusion barrier layer has a side wall surrounded by the insulating interlayer.

5. The semiconductor memory device according to claim 1, in which the noble metal element forming the adhesion layer is an element of the platinum group.

6. The semiconductor memory device according to claim 5, in which the lower electrode contains an element of the platinum group as a main component.

7. The semiconductor memory device according to claim 6, in which the noble metal element forming the adhesion layer and the noble metal element forming the lower electrode are the same.

8. The semiconductor memory device according to claim 1, in which the lower electrode is formed of a noble metal or a noble metal compound and has oxygen barrier properties.

9. The semiconductor memory device according to claim 1, in which the lower electrode is formed of at least one noble metal selected from the group consisting of iridium, ruthenium, rhodium, palladium, osmium and platinum or a compound thereof.

10. The semiconductor memory device according to claim 9, in which the noble metal element forming the adhesion layer is at least one element of the platinum group selected from the group consisting of iridium, ruthenium, rhodium, palladium, osmium and platinum, and the metal element that differs from any one of the noble metal element, an alkali element and an alkaline earth metal element is at least one metal element selected from the group consisting of hafnium, aluminum, titanium, vanadium, zirconium, niobium, molybdenum, tantalum and tungsten.

11. The semiconductor memory device according to claim 10, in which the noble metal element forming the adhesion layer and the noble metal element forming the lower electrode are the same.

12. The semiconductor memory device according to claim 10, in which the adhesion layer contains hafnium and the content of hafnium is 25 atomic % or less.

13. The semiconductor memory device according to claim 10, in which the adhesion layer contains aluminum and the content of aluminum is 50 atomic % or less.

14. The semiconductor memory device according to claim 10, in which the adhesion layer contains titanium and the content of titanium is 25 atomic % or less.

15. The semiconductor memory device according to claim 10, in which the adhesion layer contains vanadium and the content of vanadium is 25 atomic % or less.

16. The semiconductor memory device according to claim 10, in which the adhesion layer contains zirconium and the content of zirconium is 25 atomic % or less.

17. The semiconductor memory device according to claim 10, in which the adhesion layer contains niobium and the content of niobium is 25 atomic % or less.

18. The semiconductor memory device according to claim 10, in which the adhesion layer contains molybdenum and the content of molybdenum is 25 atomic % or less.

19. The semiconductor memory device according to claim 10, in which the adhesion layer contains tantalum and the content of tantalum is 25 atomic % or less.

20. The semiconductor memory device according to claim 10, in which the adhesion layer contains tungsten and the content of tungsten is 20 atomic % or less.

21. The semiconductor memory device according to claim 1, in which the diffusion barrier layer is formed of a refractory metal or a refractory metal compound, and it contains no oxygen element.

22. The semiconductor memory device according to claim 1, in which the thickness of the adhesion layer is 50
nm or less.
